(19) United States
(12) Patent Application Publication
(10) Pub. No.: US 2007/0104263 A1
(43) Pub. Date: May 10, 2007

(54) Method for adaptively tuning an equalizer

(76) Inventors: Chiao-Chih Chang, Taipei City (TW); Rong-Liang Chiou, Hsin-Chu City (TW); Cheng-I Wei, Hsin-Chu City (TW); Ming-Luen Liou, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 11/164,068

(22) Filed: Nov. 9, 2005

(51) Int. Cl. H03K 5/159; H04B 1/10

(52) U.S. Cl. 375/232; 375/350

(57) ABSTRACT

A method for adaptively tuning an equalizer is disclosed. The method includes utilizing the equalizer to process an input signal and accordingly generate an output signal, determining whether the equalizer has converged, and adjusting an equalizer step size of the equalizer according to a result of the step of determining whether the equalizer has converged.

### Background

The present invention relates to equalization, and more particularly, to a method for adaptively tuning an equalizer.

With the development of modern communication standards and the progress of VLSI technology, hard-wired and wireless communication systems are gaining in popularity and experiencing rapid growth. Wireless communication are no longer confined to lower data rate transmission schemes, such as voice services, but have now advanced to higher data rate transmission schemes such as multimedia services. However, with the increase in transmission rates and the enhancement of modulation techniques, Inter-symbol interference (ISI) caused by multi-path fading becomes increasingly harmful. Multi-path fading is a physical phenomenon in which radio waves become deflected and reflected from temperature gradients in the air, surfaces on the earth, and obstacles in the transmission path. The fading phenomenon results in several replicas of the transmitted signal appearing at the receiver end. Each replica usually arrives at a different phase because each path it travels is different. If the replicas span a period that is comparable to, or even longer than the period of a symbol, the receiver may fail to correctly identify the transmitted signal. It is therefore necessary to install an adaptive equalizer in the receiver end of the communication system in order to reduce or eliminate potential interference, and to help ensure high transmission quality.

In practice, an adaptive equalizer set in the receiver of a communication system typically comprises a digital filter with an adaptive response to compensate for channel distortion. The response of the digital filter implementing the equalizer is altered to approximate the inverse of the transfer function of the communication channel. If the response of the digital filter correctly approximates the inverse of the transfer function of the communication channel, the interference effect can be significantly reduced or eliminated. To alter the response of the digital filter, the filter coefficients used by the filter can be adjusted. Several algorithms can be used to adaptively adjust the filter coefficients and thereby alter the filter response of the equalizer. One of the more typically used algorithms is the least mean square (LMS) algorithm. In the LMS algorithm, filter coefficients of the digital filter implementing the equalizer are adaptively adjusted according to a step size of the equalizer and the calculated decision errors. Generally speaking, setting a larger step size for the equalizer allows the filter coefficients of the equalizer to converge faster. However, larger step sizes can also lead to rapid fluctuations in the filter coefficients and cause additional noise. On the contrary, setting a smaller step size for the equalizer helps the filter coefficients to remain stable. However, this will cause the convergence time for the filter coefficients to increase.

Several methods are proposed for adaptively adjusting the step size utilized by the equalizer. U.S. Pat. No. 6,490,007 discloses a signal equalization method, which is discussed in detail below. Using this method, both an adaptive equalizer and a forward error correcting (FEC) unit are set in a receiving path of the receiver. Initially, the equalizer is set with a default step size. The FEC unit detects and corrects errors in the receiving path after the signals are processed by the equalizer. The step size utilized by the equalizer is adaptively adjusted according to the packet error rate as determined by a measurement taken at the output of the FEC unit. If the measured packet error rate is above an acceptable threshold level, a different step size is set in the equalizer and another measurement for the packet error rate is performed. The step size that produces the smaller of the packet error rates is retained by the equalizer in subsequent processes.

### Summary

According to a first and a second embodiment, a method for adaptively tuning an equalizer is disclosed. The method comprises utilizing the equalizer to process an input signal and accordingly generate an output signal, determining whether the equalizer has converged, and adjusting an equalizer step size of the equalizer according to a result of the step of determining whether the equalizer has converged.

According to a third embodiment, a method for adaptively tuning an equalizer is disclosed. The method comprises utilizing the equalizer to process an input signal, determining whether there is a tendency toward occurrence of error propagation during the equalizer processing the input signal, and adjusting an equalizer step size of the equalizer according to a result of the step of determining whether there is a tendency toward occurrence of error propagation.

According to a fourth embodiment, a method for adaptively tuning an equalizer of a receiver is disclosed. The method comprises utilizing the equalizer to process an input signal, monitoring a channel variation in a communication channel utilized by the receiver, and adjusting an equalizer step size of the equalizer according to a result of the step of monitoring the channel variation in the communication channel.

### BRIEF DESCRIPTION OF THE DRAWINGS

FIG. 1 shows a flowchart for adaptively tuning an equalizer according to a first embodiment.

FIG. 2 shows a flowchart for adaptively tuning an equalizer according to a second embodiment.

FIG. 3 shows a flowchart for adaptively tuning an equalizer according to a third embodiment.

FIG. 4 shows a flowchart for adaptively tuning an equalizer according to a fourth embodiment.

FIG. 5 shows an exemplary apparatus that can be used to facilitate the flowchart shown in FIG. 4.

### DETAILED DESCRIPTION

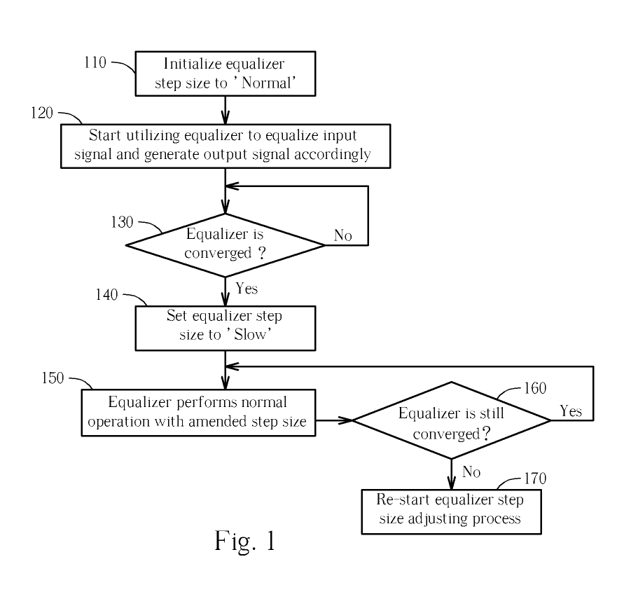

FIG. 1 shows a flowchart for adaptively tuning an equalizer according to a first embodiment. The flowchart includes the following steps:

Step 110: Initialize an equalizer step size of the equalizer to ‘Normal’.

Step 120: Start utilizing the equalizer to process (i.e. equalize) an input signal and accordingly generate an output signal.

Step 130: Determine whether the equalizer has converged or not. If the equalizer has converged, go to step 140; otherwise, delay a moment and then go back to perform step 130 again. There are some conditions, which are not taught by the related art, can be examined in this step to determine whether the equalizer has converged or not. For example, the conditions for determining that the equalizer has converged may include: (a) a signal-to-noise ratio (SNR) corresponding to the output signal is greater than a threshold value TH1, (b) a symbol error rate (SER) corresponding to the output signal is less than a threshold value TH2, and (c) the variation of equalizer coefficients of the equalizer is less than a threshold value TH3. For examining conditions (a) and (b), the SNR and SER corresponding to the output signal should be determined beforehand. For examining condition (c), a first plurality of equalizer coefficients and a second plurality of equalizer coefficients are compared to generate a plurality of absolute differences. Herein the first plurality of equalizer coefficients and the second plurality of equalizer coefficients are utilized by the equalizer at two different time points, respectively. The two time points are preferably two immediately adjacent sampling time points. The threshold value TH3 is then compared with each of the absolute differences. If at least one of the absolute differences is greater than the threshold value TH3, it is determined that the equalizer has not converged. Preferably, only when the above-mentioned three conditions (a), (b), and (c) are met, it is determined that the equalizer has converged. If even one of the conditions (a), (b), and (c) is not met, it is determined that the equalizer has not converged.

Step 140: Set the equalizer step size of the equalizer to ‘Slow’. This step basically comprises decreasing the equalizer step size when the equalizer has converged.

Step 150: Continue using the equalizer to perform normal operations with the amended step size. Since the equalizer is already converged, having the equalizer step size set to ‘Slow’ not only ensures well operations of the equalizer, but also prevents the equalizer coefficients from fluctuation.

Step 160: Determine whether the equalizer remains converged or not. If the equalizer remains converged, go back to step 150; otherwise, go to step 170. Herein the conditions for determining that the equalizer remains converged may include: (a′) the signal-to-noise ratio (SNR) corresponding to the output signal is greater than a threshold value TH1′, (b′) the symbol error rate (SER) corresponding to the output signal is less than a threshold value TH2′, and (c′) the variation of equalizer coefficients of the equalizer is less than a threshold value TH3′. Preferably, only when the above-mentioned three conditions (a′), (b′and (c′) are met, it is determined that the equalizer remains converged. If even one of the conditions (a′), (b′), and (c′) is not met, it is determined that the equalizer has lost convergence. Beside, please note that the three threshold values TH1′, TH2′, and TH3′ adopted in this step may be different from or be the same as the three threshold values TH1, TH2, and TH3 adopted in step 130.

Step 170: Re-start the equalizer step size adjusting process.

Please note that steps 160 and 1 70 shown in FIG. 1 are merely two optional steps. These two steps can probably be excluded from the flowchart of FIG. 1 according to a further embodiment of the method. Besides, although in the above-mentioned embodiment only two different values (‘Normal’ and ‘Slow’) are provided as possible values of the equalizer step size, there can be more values adaptively provided as the equalizer step size according to the result of examining whether the equalizer has converged or not.

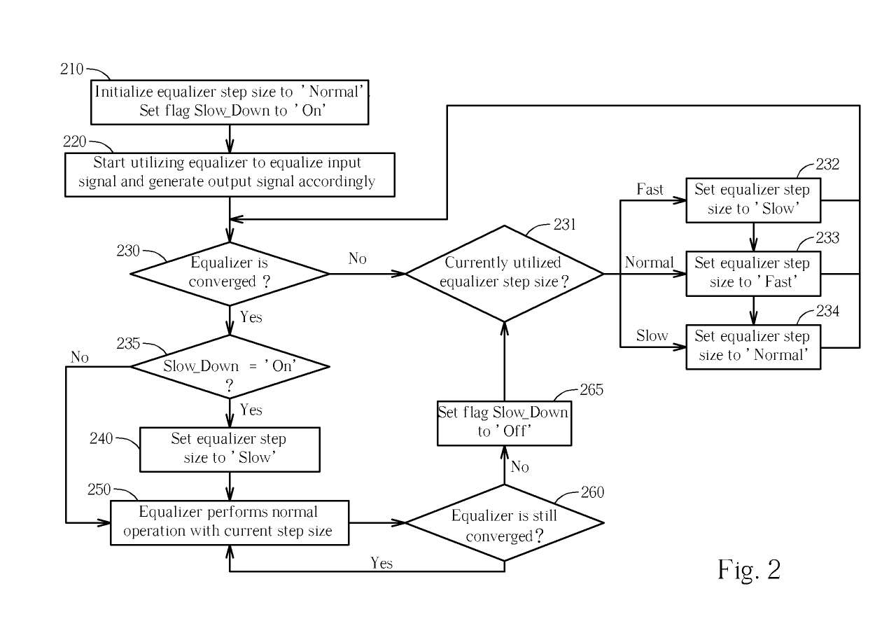

FIG. 2 shows a flowchart for adaptively tuning an equalizer according to a second embodiment. The flowchart shown in FIG. 2 includes the following steps:

Step 210: Initialize an equalizer step size of the equalizer to ‘Normal’. Set the status of a flag Slow_Down to ‘On’.

Step 220: Start utilizing the equalizer to process (i.e. equalize) an input signal and accordingly generate an output signal.

Step 230: Determine whether the equalizer has converged or not. If the equalizer has converged, go to step 235; otherwise, go to step 231. Similar to step 130, the conditions for determining that the equalizer has converged may include: (a) a signal-to-noise ratio (SNR) corresponding to the output signal is greater than a threshold value TH1, (b) a symbol error rate (SER) corresponding to the output signal is less than a threshold value TH2, and (c) the variation of equalizer coefficients of the equalizer is less than a threshold value TH3. Preferably, only when all the above-mentioned three conditions (a), (b), and (c) are met, it is determined that the equalizer has converged. If even one of the conditions (a), (b), and (c) is not met, it is determined that the equalizer has not converged.

Step 231: Determine which value is currently utilized by the equalizer as the equalizer step size. If ‘Fast’ is utilized by the equalizer as the equalizer step size, go to step 232. If ‘Normal’ is utilized by the equalizer as the equalizer step size, go to step 233. If ‘Slow’ is utilized by the equalizer as the equalizer step size, go to step 234.

Step 232: Set the equalizer step size of the equalizer to ‘Slow’.

Step 233: Set the equalizer step size of the equalizer to ‘Fast’.

Step 234: Set the equalizer step size of the equalizer to ‘Normal’.

Step 235: Determine the current status of the flag Slow_Down. If the current status of the flag Slow_Down is ‘On’, go to step 240; otherwise, go to step 250.

Step 240: Set the equalizer step size of the equalizer to ‘Slow’. In other words, once the equalizer has converged, the equalizer step size will be decreased.

Step 250: Keep on utilizing the equalizer to perform normal operations with the current step size.

Step 260: Determine whether the equalizer remains converged or not. If the equalizer remains converged, go back to step 250; otherwise, go to step 265. Similar to step 160, herein the conditions for determining that the equalizer remains converged may include: (a′) the signal-to-noise ratio (SNR) corresponding to the output signal is greater than a threshold value TH1′, (b′) the symbol error rate (SER) corresponding to the output signal is less than a threshold value TH2′, and (c′) the variation of equalizer coefficients of the equalizer is less than a threshold value TH3′. Preferably, only when the above-mentioned three conditions (a′), (b′), and (c′) are met, it is determined that the equalizer remains converged. If even one of the conditions (a′), (b′), and (c′) is not met, it is determined that the equalizer has lost convergence. Beside, please note that the three threshold values TH1′, TH2′, and TH3′adopted in this step may be different from or be the same as the three threshold values TH1, TH2, and TH3 adopted in step 230.

Step 265: Set the status of the flag Slow_Down to ‘Off’.

Please note although in the above-mentioned embodiment only three different values (‘Fast’, ‘Normal’ and ‘Slow’) are provided as possible values of the equalizer step size, there can be more values adaptively provided as the equalizer step size according to the result of examining whether the equalizer has converged or not.

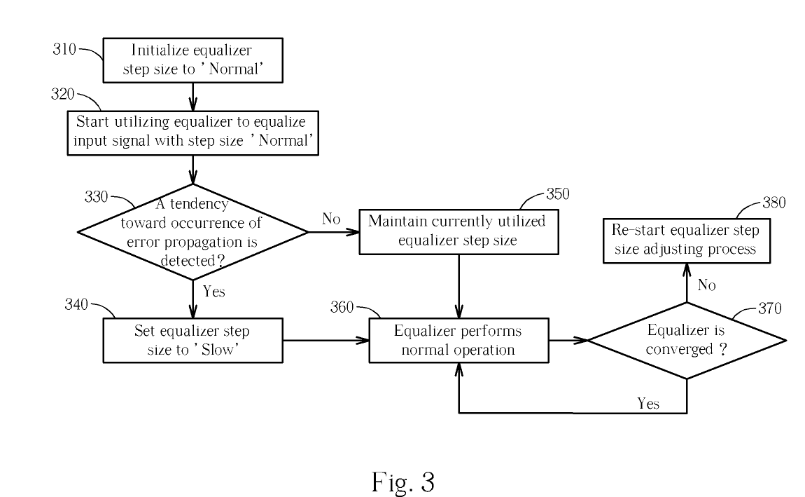

FIG. 3 shows a flowchart for adaptively tuning an equalizer according to a third embodiment. The flowchart includes the following steps:

Step 310: Initialize an equalizer step size of the equalizer to ‘Normal’.

Step 320: Start utilizing the equalizer to process (i.e. equalize) an input signal with the step size ‘Normal’.

Step 330: Determine whether there is a tendency toward occurrence of error propagation. If a tendency toward occurrence of error propagation is detected, go to step 340; otherwise, go to step 350. There are several reasons that may cause error propagation to occur during the equalizer performing the equalization process. One possible reason is that at least one of the equalizer coefficients (except for a main-path coefficient) utilized by the equalizer has an uncommonly large value. The uncommonly large value existing in the equalizer coefficients might cause a high power echo, which can be thought of as a form of error propagation, to appear. The high power echo may erroneously diverge the equalizer coefficients. Therefore, as an example, whether a tendency toward occurrence of error propagation exists or not can be determined through analyzing the equalizer coefficients of the equalizer. This is accomplished by comparing a threshold value TH4 with a plurality of absolute values of a plurality of equalizer coefficients (except for the main-path equalizer coefficient). If at least one of the absolute values is greater than the threshold value TH4, it is determined that a tendency toward occurrence of error propagation is detected.

Step 340: Set the equalizer step size of the equalizer to ‘Slow’. The reason of decreasing the equalizer step size in this step is to prevent the equalizer coefficients from being diverged erroneously by the high power echo.

Step 350: Maintain the currently utilized equalizer step size ‘Normal’.

Step 360: Keep on utilizing the equalizer to perform normal operations (with the equalizer step size being either ‘Slow’ or ‘Normal’).

Step 370: Determine whether the equalizer has converged or not. If the equalizer has converged, go back to step 360; otherwise, go to step 380. Herein the conditions for determining that the equalizer has converged may include: (a) a signal-to-noise ratio (SNR) corresponding to the output signal is greater than a threshold value TH1, (b) a symbol error rate (SER) corresponding to the output signal is less than a threshold value TH2, and (c) the variation of equalizer coefficients of the equalizer is less than a threshold value TH3. Preferably, only when the above-mentioned three conditions (a), (b), and (c) are met, it is determined that the equalizer has converged. If even one of the conditions (a), (b), and (c) is not met, it is determined that the equalizer has not converged.

Step 380: Re-start the equalizer step size adjusting process.

Please note that steps 370 and 380 shown in FIG. 3 are merely two optional steps. These two steps can also be excluded from the flowchart of FIG. 3 according to another embodiment. Besides, although in the above-mentioned embodiment only two different values (‘Normal’ and ‘Slow’) are provided as possible values of the equalizer step size, a further embodiment there can comprise more possible value to be adaptively used as the equalizer step size.

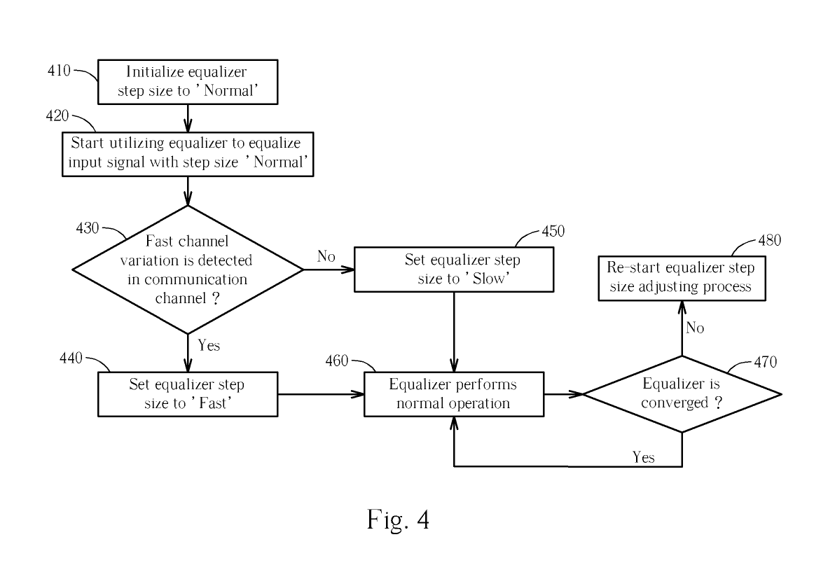

FIG. 4 shows a flowchart for adaptively tuning an equalizer according to a fourth embodiment. The equalizer is set in a signal-processing path of a receiver. The flowchart includes the following steps:

Step 410: Initialize an equalizer step size of the equalizer to ‘Normal’.

Step 420: Start utilizing the equalizer to process an input signal with the step size ‘Normal’.

Step 430: Determining whether there is a fast channel variation in a communication channel utilized by the receiver. If a fast channel variation is detected in the communication channel, go to step 440; otherwise, go to step 450. This step is performed through monitoring a channel variation of the communication channel utilized by the receiver. There are several ways that can be adopted in this step to monitor the channel variation of the communication channel. However, in order to preserve the continuity of this flowchart description, examples of the ways for monitoring the channel variation will be described later.

Step 440: Set the equalizer step size of the equalizer to ‘Fast’. One of the reasons for increasing the equalizer step size in this step is to use larger equalizer step size to increase the adoption speed of the equalizer so as to reduce/eliminate the negative effects caused by the fast channel variation in the communication channel. Except for setting the equalizer step size to ‘Fast’, alternatively, the previously utilized equalizer step size ‘Normal’ can also be maintained in this step.

Step 450: Set the equalizer step size of the equalizer to ‘Slow’. One of the reasons of decreasing the equalizer step size in this step is that since no fast channel variation is detected, having the equalizer step size set to ‘Slow’ can ensure well operation of the equalizer and prevent the equalizer coefficients of the equalizer from fluctuation.

Step 460: Keep on utilizing the equalizer to perform normal operations (with the equalizer step size being either ‘Slow’, or ‘Normal’, or ‘Fast’).

Step 470: Determine whether the equalizer has converged or not. If the equalizer has converged, go back to step 460; otherwise, go to step 480. Herein the conditions for determining that the equalizer has converged may include: (a) a signal-to-noise ratio (SNR) corresponding to the output signal is greater than a threshold value TH1, (b) a symbol error rate (SER) corresponding to the output signal is less than a threshold value TH2, and (c) the variation of equalizer coefficients of the equalizer is less than a threshold value TH3. Preferably, only when the above-mentioned three conditions (a), (b), and (c) are met, it is determined that the equalizer has converged. If even one of the conditions (a), (b), and (c) is not met, it is determined that the equalizer has not converged.

Step 480: Re-start the equalizer step size adjusting process.

Please note that steps 470 and 480 shown in FIG. 4 are merely two optional steps. These two steps can also be excluded from the flowchart in FIG. 4 according to another embodiment. Besides, although in the above-mentioned embodiment only three different values (‘Fast’, ‘Normal’, and ‘Slow’) are provided as possible values of the equalizer step size, there can be more values adaptively provided as the equalizer step size in other embodiments.

Referring back to step 430, there are several methods available for monitoring the channel variation of the communication channel. A first example comprises analyzing the equalizer coefficients of the equalizer. More specifically, a first plurality of equalizer coefficients and a second plurality of equalizer coefficients are compared to generate a plurality of absolute differences. Herein the first plurality of equalizer coefficients and the second plurality of equalizer coefficients are utilized by the equalizer at two different time points, respectively. The two time points are preferably two immediately adjacent sampling time points. A threshold value TH5 is then compared with each of the absolute differences. If at least one of the absolute differences is greater than the threshold value TH5, it is determined that a fast channel variation is detected in the communication channel.

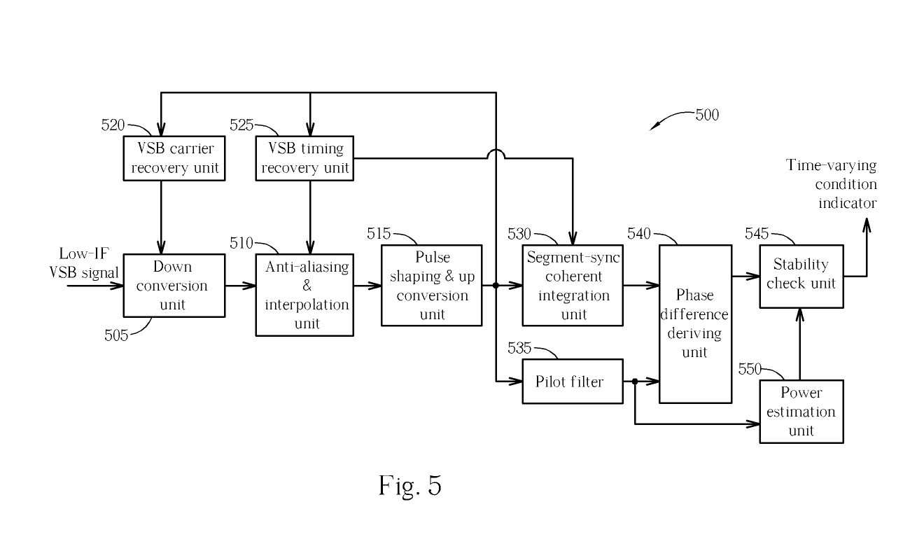

In the case that the receiver is an eight-level vestigial sideband (8-VSB) receiver or another similar device, the channel variation of the communication channel can be monitored through other manners in step 430. FIG. 5 shows an exemplary apparatus 500 that can be used in the 8-VSB receiver to monitor the channel variation of the communication channel. The apparatus 500 includes a down conversion unit 505, an anti-aliasing & interpolation unit 510, a pulse shaping & up conversion unit 515, a VSB carrier recovery unit 520, a VSB timing recovery unit 525, a segment-sync coherent integration unit 530, a pilot filter 535, a phase difference deriving unit 540, a stability check unit 545, and a power estimation unit 550. A low-IF VSB signal constitutes the input of the apparatus 500; a time-varying condition indicator constitutes the output of the apparatus 500. The apparatus 500 can be shared with the original receiver since it's a normal operation in VSB demodulating process.

The down conversion unit 505, anti-aliasing & interpolation unit 510, and pulse shaping & up conversion unit 515 are responsible for a typical VSB demodulation flow that converts the low-IF VSB signal into a VSB symbol stream. The VSB carrier recovery unit 520 tracks and compensates for residual pilot frequency offset so that the pilot existing in the VSB symbol stream is accurately locked at DC. The VSB timing recovery unit 520 tracks and compensates for transmitter/receiver oscillator frequency mismatch so that the symbol timing will not drift. The pilot filter 535 extracts a pilot signal component from the VSB symbol stream. The segment-sync coherent integration unit 530 generates a segment-sync integrated signal from the VSB symbol stream. More specifically, the segment-sync coherent integration unit 530 matches the segment-sync symbols inserted at the start of each segment of the VSB symbol stream, while the segment-start timing is provided by the VSB timing recovery unit 525.

After carrier/timing recovery is completed, a phase difference between the pilot signal component and the segment-sync integrated signal is monitored. More specifically, at a first time point the phase difference deriving unit 540 derives a first phase difference between the pilot signal component and the segment-sync integrated signal. At a second time point the phase difference deriving unit 540 derives a second phase difference between the pilot signal component and the segment-sync integrated signal. The stability check unit 545 then derives a difference variation between the first phase difference and the second phase difference. The stability check unit 545 also compares a threshold value TH6 with the difference variation. If the difference variation is greater than the threshold value TH6, it is determined that there is a fast channel variation in the communication channel. The determination result is reported through the time-varying condition indicator generated by the stability check unit 545. The decision to perform step 440 or 450 can then be determined according to the time-varying condition indicator.

The power estimation unit 550 in this example is merely an optional component. When the pilot signal component has a low level, the derived phase difference between the pilot signal component and the segment-sync integrated signal becomes less accurate. Hence the power estimation unit 550 included in this example is responsible for the power estimation process, and let the stability check unit 545 to determine the reliability of the time-varying condition indicator according to the power level of the pilot signal component deduced by the power estimation unit 550.

Please note that the apparatus 500 shown in FIG. 5 only serves as an exemplary apparatus that can be installed in an 8-VSB receiver to monitor the channel variation of a communication channel utilized by the 8-VSB receiver. However, the exemplary apparatus shown in FIG. 5 does not limit the scope of the embodiment of the present invention.

What is claimed is:

1. A method for adaptively tuning an equalizer, the method comprising:
utilizing the equalizer to process an input signal and accordingly generate an output signal;
determining whether the equalizer has converged; and
adjusting an equalizer step size of the equalizer according to a result of the step of determining whether the equalizer has converged.

2. The method of claim 1, wherein the step of adjusting the equalizer step size comprises:
decreasing the equalizer step size if the equalizer has converged.

3. The method of claim 1, wherein the step of determining whether the equalizer has converged comprises:
determining a signal-to-noise ratio (SNR) corresponding to the output signal;
comparing the SNR with a threshold value; and
determining that the equalizer has not converged if the SNR is less than the threshold value.

4. The method of claim 1, wherein the step of determining whether the equalizer has converged comprises:
determining a symbol error rate (SER) corresponding to the output signal;
comparing the SER with a threshold value; and
determining that the equalizer has not converged if the SER is greater than the threshold value.

5. The method of claim 1, wherein the step of determining whether the equalizer has converged comprises:
comparing a first plurality of equalizer coefficients with a second plurality of equalizer coefficients to generate a plurality of absolute differences, the first plurality of equalizer coefficients and the second plurality of equalizer coefficients being utilized by the equalizer at two different time points, respectively; and
comparing a threshold value with each of the absolute differences; and
determining that the equalizer has not converged if at least one of the absolute differences is greater than the threshold value.

6. A method for adaptively tuning an equalizer of a receiver, the method comprising:
utilizing the equalizer to process an input signal;
monitoring a channel variation in a communication channel utilized by the receiver; and
adjusting an equalizer step size of the equalizer according to a result of the step of monitoring the channel variation in the communication channel.

7. The method of claim 6, wherein the step of monitoring the channel variation in the communication channel comprises:
analyzing equalizer coefficients of the equalizer at two different time points.

8. The method of claim 7, wherein the step of analyzing equalizer coefficients of the equalizer at two different time points comprises:
comparing a first plurality of equalizer coefficients with a second plurality of equalizer coefficients to generate a plurality of absolute differences, the first plurality of equalizer coefficients and the second plurality of equalizer coefficients being utilized by the equalizer at a first time point and a second time point, respectively; and
comparing a threshold value with each of the absolute differences.

9. The method of claim 8, wherein the step of monitoring the channel variation in the communication channel further comprises:
determining that a fast channel variation is detected in the communication channel if at least one of the absolute differences is greater than the threshold value.

10. The method of claim 9, wherein the step of adjusting the equalizer step size comprises:
decreasing the equalizer step size if no fast channel variation is detected in the communication channel.

11. The method of claim 9, wherein the step of adjusting the equalizer step size comprises:
increasing the equalizer step size if fast channel variation is detected in the communication channel.

12. The method of claim 6, wherein the receiver is an eight-level vestigial sideband (8-VSB) receiver, and the step of monitoring the channel variation in the communication channel comprises:
extracting a pilot signal component from a VSB symbol stream generated by the 8-VSB receiver;
generating a segment-sync integrated signal from the VSB symbol stream; and
monitoring a phase difference between the pilot signal component and the segment-sync integrated signal.

13. The method of claim 12, wherein the step of monitoring the phase difference between the pilot signal component and the segment-sync integrated signal comprises:
deriving a first phase difference between the pilot signal component and the segment-sync integrated signal at a first time point;
deriving a second phase difference between the pilot signal component and the segment-sync integrated signal at a second time point;
deriving a difference variation between the first phase difference and the second phase difference; and
comparing a threshold value with the difference variation.

14. The method of claim 1 3, wherein the step of monitoring the phase difference between the pilot signal component and the segment-sync integrated signal further comprises:
determining that there is a fast channel variation in the communication channel if the difference variation is greater than the threshold value.

15. The method of claim 14, wherein the step of adjusting the equalizer step size comprises:
decreasing the equalizer step size if no fast channel variation is detected in the communication channel.

16. The method of claim 14, wherein the step of adjusting the equalizer step size comprises:
increasing the equalizer step size if fast channel variation is detected in the communication channel.

17. A method for tuning an equalizer adaptively, the method comprising: utilizing the equalizer to process an input signal;
determining whether there is a tendency toward occurrence of error propagation during the equalizer processing the input signal; and
adjusting an equalizer step size of the equalizer according to a result of the step of determining whether there is a tendency toward occurrence of error propagation.

18. The method of claim 17 wherein the step of adjusting the equalizer step size comprises:
decreasing the equalizer step size if there is a tendency toward occurrence of error propagation.

19. The method of claim 17 wherein the step of determining whether there is a tendency toward occurrence of error propagation comprises:
comparing a threshold value with a plurality of absolute values of a plurality of equalizer coefficients except for a main-path equalizer coefficient; and
determining that there is a tendency toward occurrence of error propagation if at least one of the absolute values is greater than the threshold value.

20. The method of claim 17, wherein the step of adjusting the equalizer step size comprises:
decreasing the equalizer step size if there is a tendency toward occurrence of error propagation.
